(19) United States
(12) Patent Application Publication
(10) Pub. No.: US 2013/0126333 A1
(43) Pub. Date: May 23, 2013

(54) Magnetic Field Configuration For Energetic Plasma Surface Treatment and Energetic Deposition Conditions

(71) Applicant: Klaus Brondum, Ann Arbor, MI (US)

(72) Inventor: Klaus Brondum, Ann Arbor, MI (US)

(73) Assignee: VAPOR TECHNOLOGIES, INC., Longmont, CO (US)

(21) Appl. No.: 13/302,276

(22) Filed: Nov. 22, 2011

(51) Int. Cl. C23C 14/35

(52) U.S. Cl. 204/192.12; 204/298.16; 204/298.06

(57) ABSTRACT

A vacuum deposition system for forming a dense coating includes a substrate holder for holding a substrate having a substrate surface to be coated, a magnetic field generator, an optional electron source, an optional electron drain, and a deposition source. The magnetic field generator generates a magnetic field in which the substrate is at least partially immersed such that a component of the magnetic field is parallel to the substrate surface such that electrons are forced along a path that causes ionization in the vicinity of the substrate surface. The magnetic field strength at the substrate surface is between 5 and 1000 Gauss. The deposition source provides material to coat the substrate. The vacuum deposition system includes the optional electron source if the deposition source does not provide a source of electrons. A method for depositing a dense coating is also provided.

### BACKGROUND OF THE INVENTION

1. Field of the Invention

In at least one aspect, the present invention relates to methods and systems for depositing dense films on a substrate.

2. Background Art

The success of the broad spectrum of physical vapor deposition (PVD) processing is based on energetic species generated from an evaporation source and transferred via a plasma to a substrate. The plasma generated in these PVD conditions is a mixture of electrons, ions, neutrals in ratios characteristic for the source, operational pressure, and background gas.

Optimal control over the depositing species is achieved when the plasma has a high ratio of cations to neutrals and anions. The prior art has focused on creating ion sources that produce high ratios of cations to neutrals and anions. In general, these processes are conducted at lower pressures in order for the cations to reach the substrate without losing energy in their path to low energy plasma species (mean free path considerations). Cations that arrive at the substrate affect cleaning, sputtering, in-diffusion, and film deposition. The energy loss of the cations or rather averaging is the art known as thermalization. For example, arc evaporation can create cation to neutral ratio in the +90% range, magnetron sputtering in the 5% range, high power impulse magnetron sputtering (HIPIMS) up to about 50%, and ion sources near 100%. The high range cation ratios typically come with a price of low plasma concentration (end Hall, hollow cathode) and associated low deposition rate. Such processes require expensive control systems and power supply infrastructures. Moreover, many of these processes are inherently contaminated with species such as macroscopic particles that end up in the developing film greatly diminishing the applicability of the technologies for large volume production.

Accordingly, there is a need for a process that can lower the cost of producing high cation ratios that allow the formation of high density defect-free coatings.

### SUMMARY OF THE INVENTION

The present invention solves one or more problems of the prior art by providing a vacuum deposition system for forming dense coatings on a substrate. The vacuum deposition system includes a substrate holder for holding a substrate having a substrate surface to be coated, a magnetic field generator, an optional electron source, an electron drain, and a deposition source. The magnetic field generator generates a magnetic field in which the substrate is at least partially immersed such that a component of the magnetic field is parallel to the substrate surface. Characteristically, the magnetic field at the substrate surface is between 5 and 1000 Gauss. The deposition source provides material to coat the substrate. The vacuum deposition system includes the optional electron source if the deposition source does not provide a source of electrons.

In another embodiment, a vacuum deposition system for forming dense coatings is provided. The vacuum deposition system includes an electron source, an electron drain, a substrate having a substrate surface to be coated, a solenoidal magnetic field generator, and a deposition source that provides material to coat the substrate. The solenoidal magnetic field generator generates a magnetic field in which the substrate is at least partially immersed such that a component of the magnetic field is parallel to the substrate surface, the magnetic field strength at the substrate surface being between 5 and 1000 Gauss.

In still another embodiment, a method of coating a substrate with a dense coating is provided. The method includes a step of providing a substrate having a substrate surface, generating a magnetic field in which the substrate is at least partially immersed, passing an electron current through the magnetic field, and depositing material on the substrate from a deposition source. The magnetic field is such that a component of the magnetic field is parallel to the substrate surface and the magnetic field strength at the substrate surface is between 5 and 1000 Gauss.

### BRIEF DESCRIPTION OF THE DRAWINGS

FIG. 1 is a schematic illustration of a system using a magnetic field to increase coating density;

FIG. 2A provides a variation of the system of FIG. 1 that is suitable for implantation, nitriding, carbiding, and plasma enhanced chemical vapor deposition;

FIG. 2B provides a variation of the system of FIG. 1 that is suitable for thermal evaporation and PECVD;

FIG. 2C provides a variation of the system of FIG. 1 that is suitable for electron beam evaporation;

FIG. 2D provides a variation of the system of FIG. 1 that is suitable for magnetron sputtering or arc evaporation;

FIG. 3A is a schematic illustration for a variation of FIG. 1 for a linear sputtering system;

FIG. 3B provides the related contour field lines for the system of FIG. 3A;

FIG. 4A is a schematic illustration for a variation of FIG. 1 for a linear sputtering system;

FIG. 4B provides the magnetic field contours for the system of FIG. 4A with the magnetrons turned on and the solenoids off;

FIG. 4C provides the magnetic field contours for the system of FIG. 4A with the magnetrons turned on and the solenoids on;

FIG. 4D provides the magnetic field contours for the system of FIG. 4A with the magnetrons turned on and the reversed solenoids on relative to 4C;

FIG. 5 provides the flux density along direction defined by a central horizontal line traversed by substrates

FIG. 6 provides the flux density along direction defined by a central horizontal line traversed by substrates

FIG. 7A provides a schematic cross section of a system having a curved solenoid;

FIG. 7B provides the magnetic field contour line produced from the configuration of FIG. 7A;

FIG. 8 provides a generalized plot of the potential from a magnetron cathode to anode;

FIG. 9 provides a generalized resistance profile from magnetron sputter cathode surface towards anode assuming declining magnetic field from target surface of magnetron approaching vacuum permeability towards anode.

FIG. 10 provides the generalized current density profile from magnetron sputter cathode surface towards anode assuming declining magnetic field contribution from target surface of magnetron;

FIG. 11 provides the principle resistance profile of this invention from magnetron sputter cathode surface towards anode assuming contribution from the declining magnetic field from target surface of magnetron (solid line) in addition to contributions from solenoids (broken line); and

FIG. 12 provides the principle current density profile of this invention from magnetron sputter cathode surface towards anode assuming contribution from the declining magnetic field from target surface of magnetron (solid line) in addition to contributions from solenoids (broken line).

### DETAILED DESCRIPTION OF THE PREFERRED EMBODIMENT(S)

Reference will now be made in detail to presently preferred compositions, embodiments and methods of the present invention, which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

Except in the examples, or where otherwise expressly indicated, all numerical quantities in this description indicating amounts of material or conditions of reaction and/or use are to be understood as modified by the word “about” in describing the broadest scope of the invention. Practice within the numerical limits stated is generally preferred. Also, unless expressly stated to the contrary: percent, “parts of,” and ratio values are by weight; the description of a group or class of materials as suitable or preferred for a given purpose in connection with the invention implies that mixtures of any two or more of the members of the group or class are equally suitable or preferred; the first definition of an acronym or other abbreviation applies to all subsequent uses herein of the same abbreviation and applies mutatis mutandis to normal grammatical variations of the initially defined abbreviation; and, unless expressly stated to the contrary, measurement of a property is determined by the same technique as previously or later referenced for the same property.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

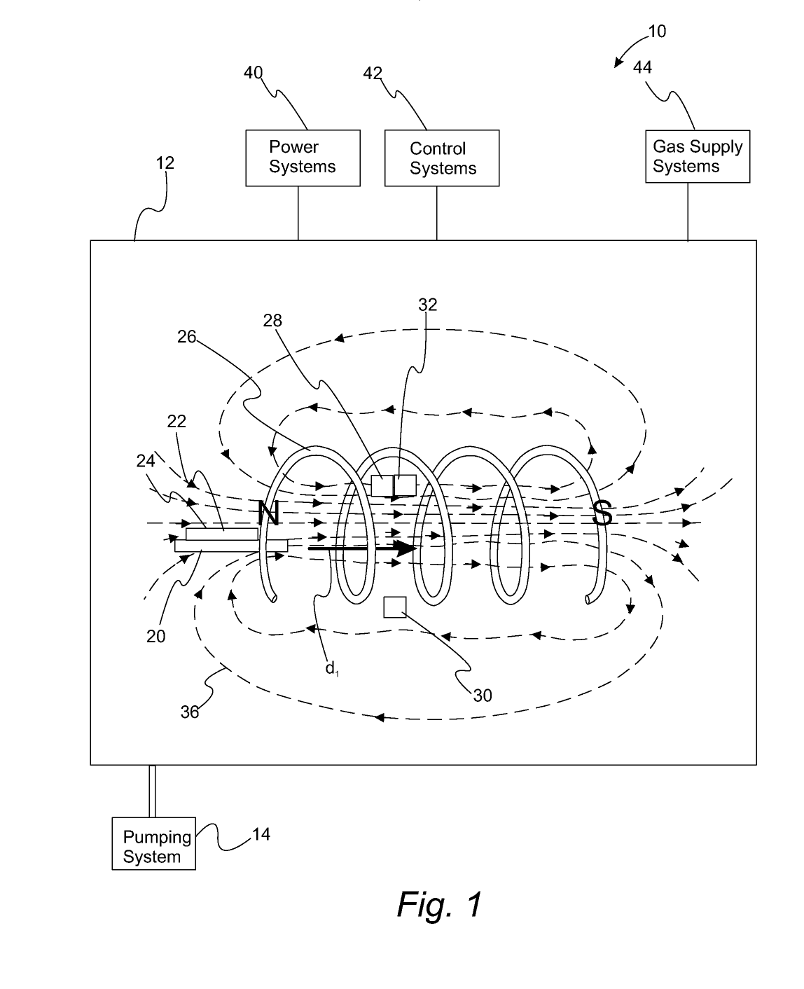

With reference to FIG. 1, a vacuum deposition system for forming dense coatings on a substrate is provided. Vacuum deposition system 10 includes vacuum chamber 12 which is maintained under reduced pressure via pumping system 14. Vacuum deposition system 10 includes substrate holder 20 for holding substrate 22, having substrate surface 24 to be coated, magnetic field generator 26, optional electron source 28, electron drain 30, and deposition source 32. Magnetic field generator 26 generates magnetic field 36 in which substrate 22 is at least partially immersed such that the magnetic field is substantially parallel to the substrate surface and to the substrate trajectory. Advantageously, such parallel components force electrons along a path that causes ionization in the vicinity of the substrate surface. North and south of the magnetic field are labeled as “N” and “S”, respectively. In this context “substantially parallel” means that the component of the magnetic field that is parallel to the substrate surface or the trajectory of substrate surface movement has on average a magnitude greater than 50% of the total magnitude of the magnetic field. More particularly, the component of the magnetic field that is parallel to the substrate surface or the trajectory of substrate surface movement has on average a magnitude that is greater than 80% of the total magnitude of the magnetic field. Most particularly, the component of the magnetic field that is parallel to the substrate surface or the trajectory of substrate surface movement has on average a magnitude that is greater than 90% of the total magnitude of the magnetic field. Substrate 22 may be electrically floating or it may be negatively biased. In a refinement, magnetic field 36 has a field strength at substrate surface 24 between 5 and 1000 Gauss. In another refinement, magnetic field 36 is periodically reversed at a frequency between 0.1 and 110 Hz. Deposition source 32 provides material to coat substrate 22. Examples of suitable depositions sources include sputtering sources, evaporation sources, arc depositions sources, and the like. Vacuum deposition system 10 includes optional electron source 28 if deposition source 32 does not provide a source of electrons. Optional electron drain 30 is used to close the circuit for the electrons provided by electron source 32.

In a variation of the present embodiment, magnetic field generator 26 is a solenoidal magnetic field generator (e.g., a coil) which includes a plurality of windings 34 (i.e., a solenoid). The coil produces a solenoidal magnetic field. In one refinement as depicted in FIG. 1, magnetic field generator 26 has a linear configuration in which the coil windings are about an axis. In such a configuration, substrate 22 moves linearly through magnetic field 36 along direction d₁. In another refinement which is described in more detail below, magnetic field generator 26 has an axial configuration such that the substrate moves axially through magnetic field 36. In this latter configuration, the coils are wound about an arc of a circle. In still another refinement, magnetic field 36 has a rectangular cross section.

FIG. 1 also depicts power system 40 for supplying power to magnetic field generator 26, any substrate heaters, and the material source if needed. Control system 42 is used to control magnetic field generator 26, substrate heaters if present, movement of the substrate holder, and the material source if needed. Gas supply system 44 provides reaction or background gases as needed.

The present embodiment is adaptable to a number of thin film depositions techniques. For example, vacuum deposition system 10 may operate in sputtering mode, arc deposition mode, or electron beam evaporation mode. In general, any given system will be designed to operate in only one of these modes.

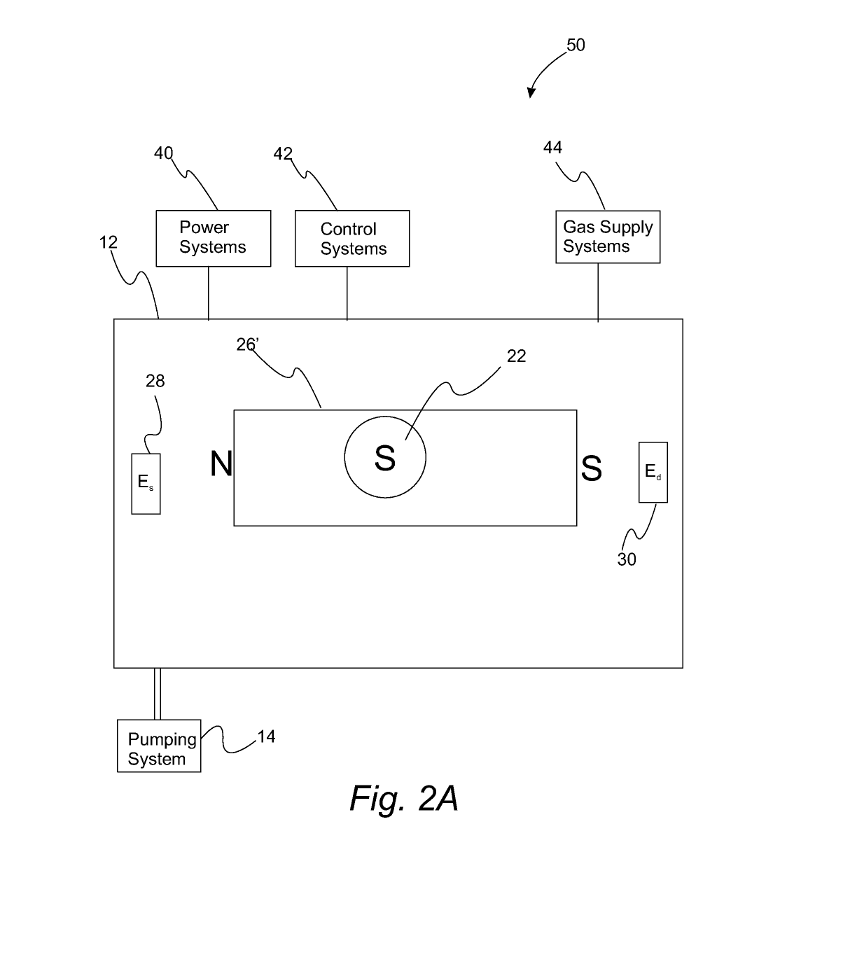

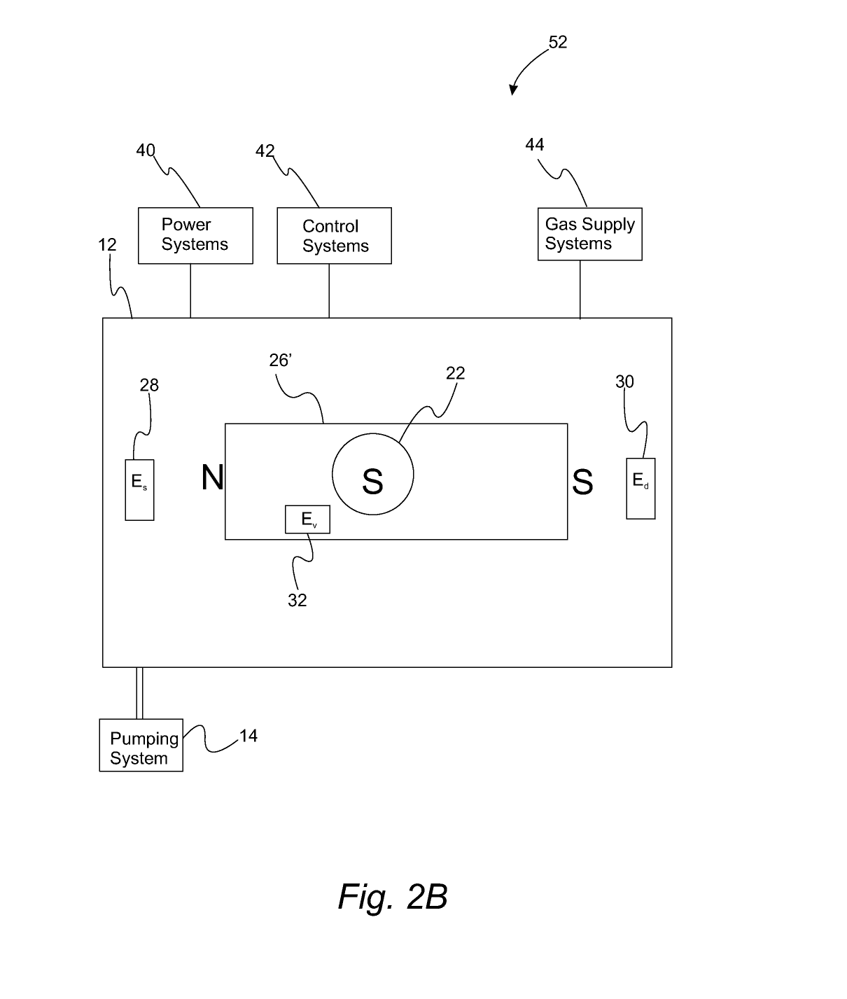

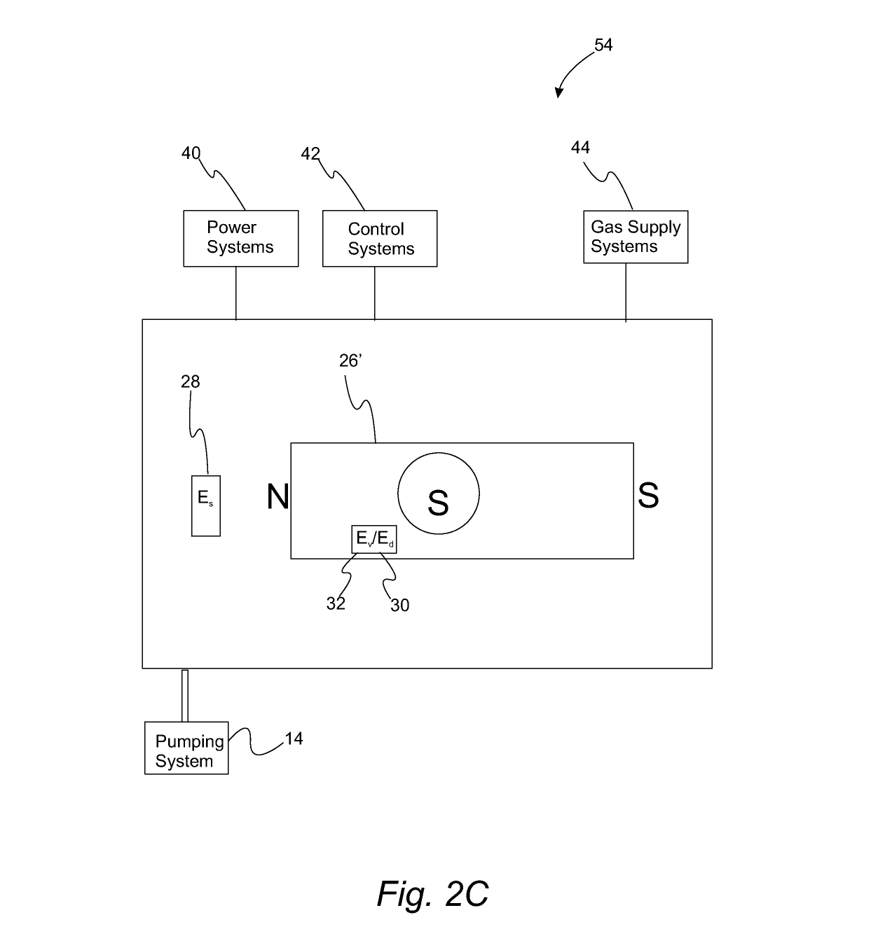

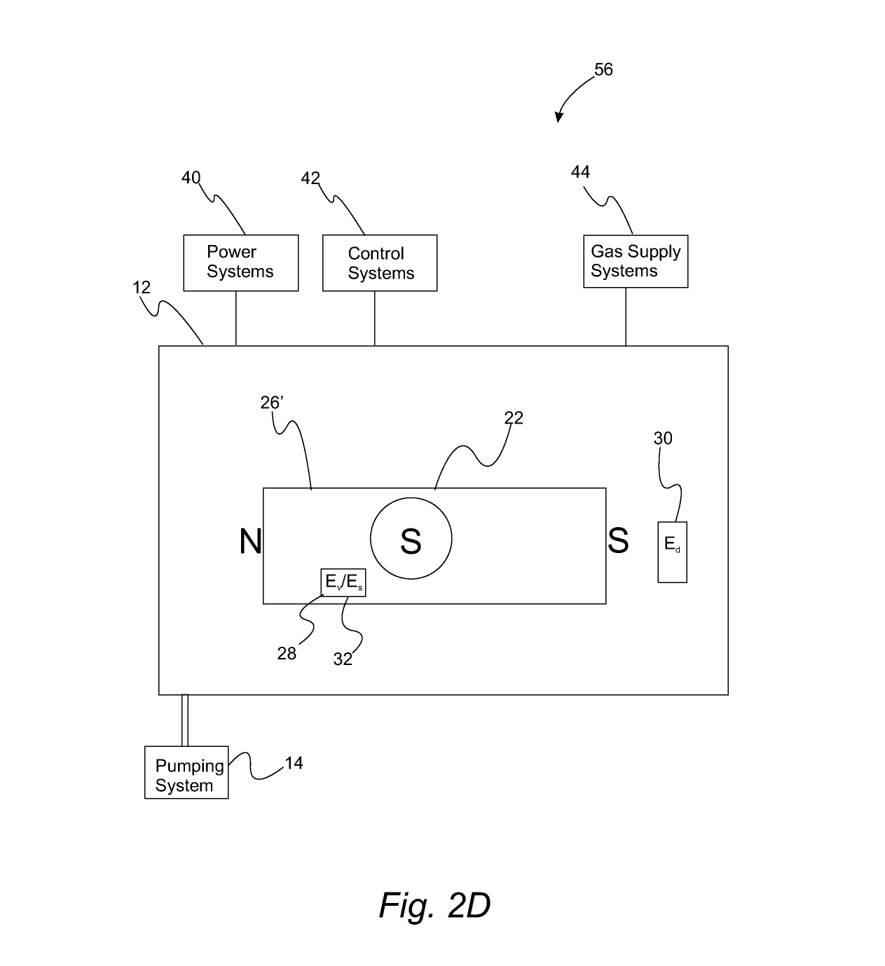

With reference to FIGS. 2A, 2B, 2C, and 2D, schematic illustrations of variations of an apparatus for producing dense coatings are provided. FIG. 2A provides a variation of the system of FIG. 1 that is suitable for implantation, nitriding, carbiding, and plasma enhanced chemical vapor deposition (PECVD). System 50 includes substrate 22 positioned within solenoid 26′. In this configuration, electron source 28 and electron drain 30 are positioned within deposition chamber 12 but not within solenoid 26′. Gas is supplied to reaction chamber 12 via gas supply system 44. For example, nitrogen gas is supplied for nitriding, reactive gases for PECVD, etc. FIG. 2B provides a variation of the system of FIG. 1 that is suitable for thermal evaporation and PECVD. System 52 includes substrate 22 positioned within solenoid 26′. In this configuration, electron source 28 and electron drain 30 are positioned within deposition chamber 12 but not within solenoid 26′. Deposition source 32 is placed within solenoid 26′. Gas is supplied to reaction chamber 12 via gas supply system 44. FIG. 2C provides a variation of the system of FIG. 1 that is suitable for electron beam evaporation. System 54 includes substrate 22 positioned within solenoid 26′. In this configuration, electron source 28 is positioned within deposition chamber 12 but not within solenoid 26′. Deposition source 32 is placed within solenoid 26′. In this variation, deposition source 32 and electron drain 30 are in close proximity or combined together, for example, a metal crucible holding material to be deposited. Gas, if needed, is supplied to reaction chamber 12 via gas supply system 44. FIG. 2D provides a variation of the system of FIG. 1 that is suitable for magnetron sputtering or arc evaporation. System 56 includes substrate 22 positioned within solenoid 26′. In this configuration, electron source 28 and deposition source 32 are the same component (e.g., the cathode in magnetron sputtering) and are positioned within solenoid 26′. In this variation, electron drain 30 is positioned with deposition chamber 12 but outside of solenoid 26′. Gas is supplied to reaction chamber 12 via gas supply system 44.

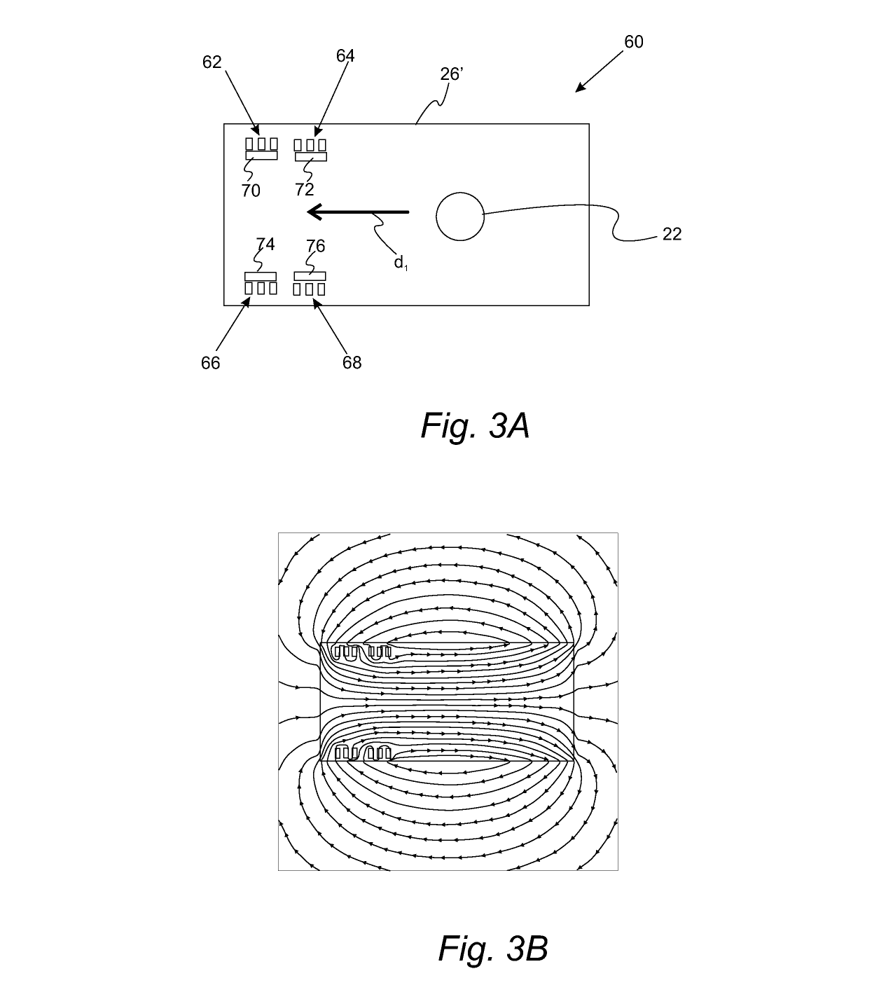

With reference to FIGS. 3A and 3B, a schematic illustration for a variation of FIG. 1 for a linear sputtering system is provided. FIG. 3A is a schematic of the system configuration in the vicinity of the solenoid while FIG. 3B provides the related contour field lines. System 60 includes groups of permanent magnets 62-68 for four magnetrons, solenoid 26′, and substrate 12. Cathode targets 70-76 are also depicted in FIG. 3A. In this configuration, substrate 22 traverses the x axis from right to left along direction d₁ while rotating for optimum three dimensional coverage. The linear concept is especially interesting as it lends itself well to in-line coaters preferred for high throughput requirements.

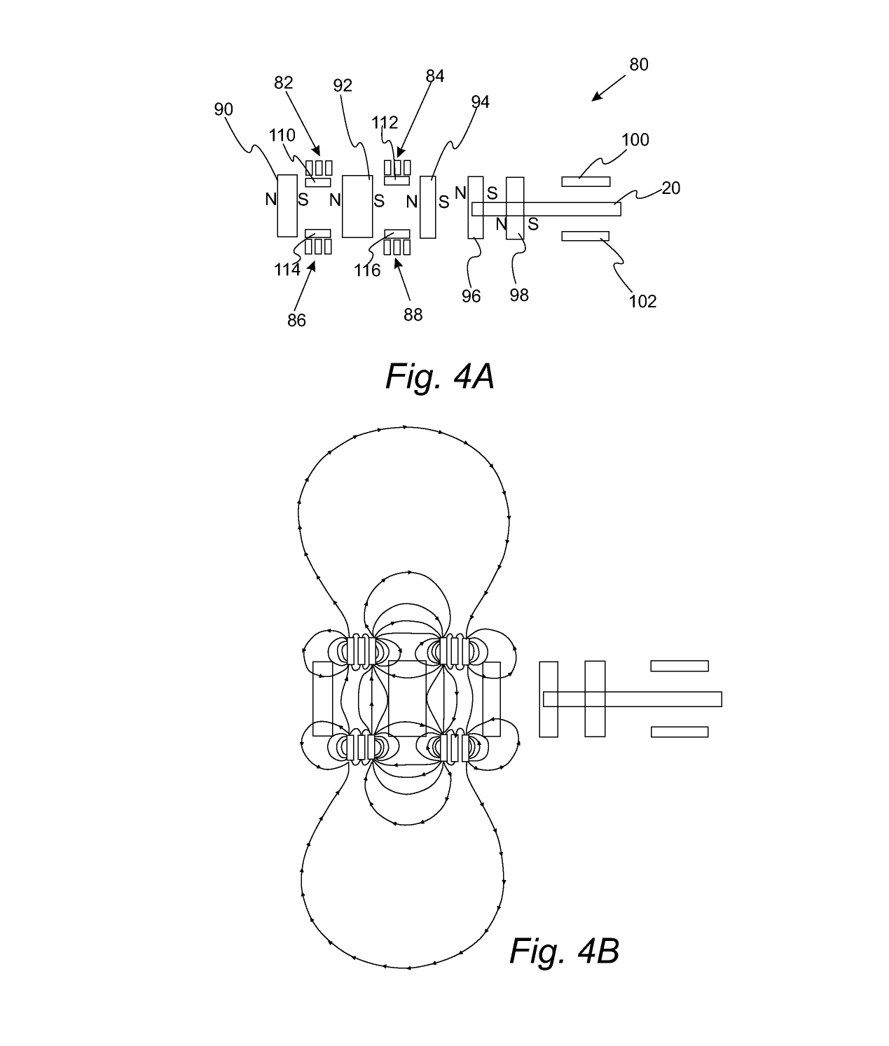

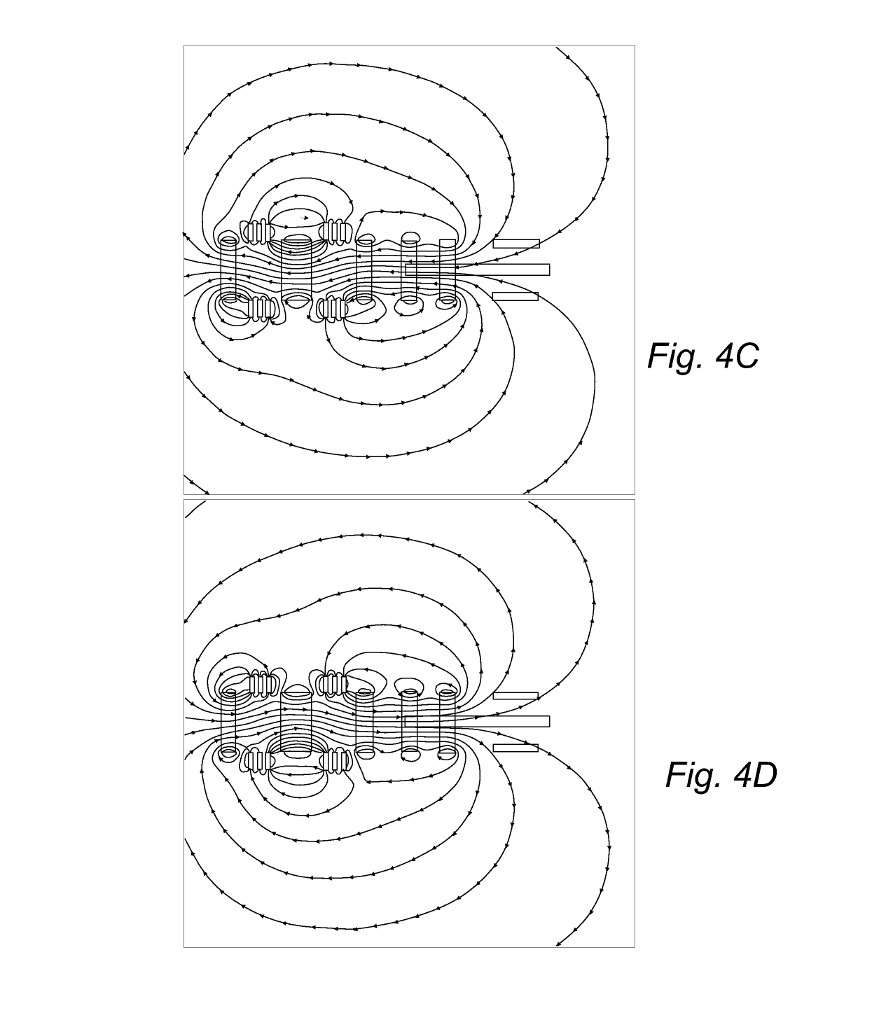

With reference to FIGS. 4A-D, a schematic illustration and related magnetic field contours for a variation of FIG. 1 for a linear sputtering system are provided. FIG. 4A is a schematic illustration for a variation of FIG. 1 for a linear sputtering system. System 80 includes groups of permanent magnets 82-88 for four magnetrons, solenoids 90-98, and substrate holder 20. System 80 also includes two horizontal anodes or electron drains 100, 102. FIG. 4B provides the magnetic field contours with the magnetrons turned on and the solenoids off. FIG. 4C provides the magnetic field contours with the magnetrons turned on and the solenoids on. FIG. 4D provides the magnetic field contours with the magnetrons turned on and the solenoids on in reverse field.

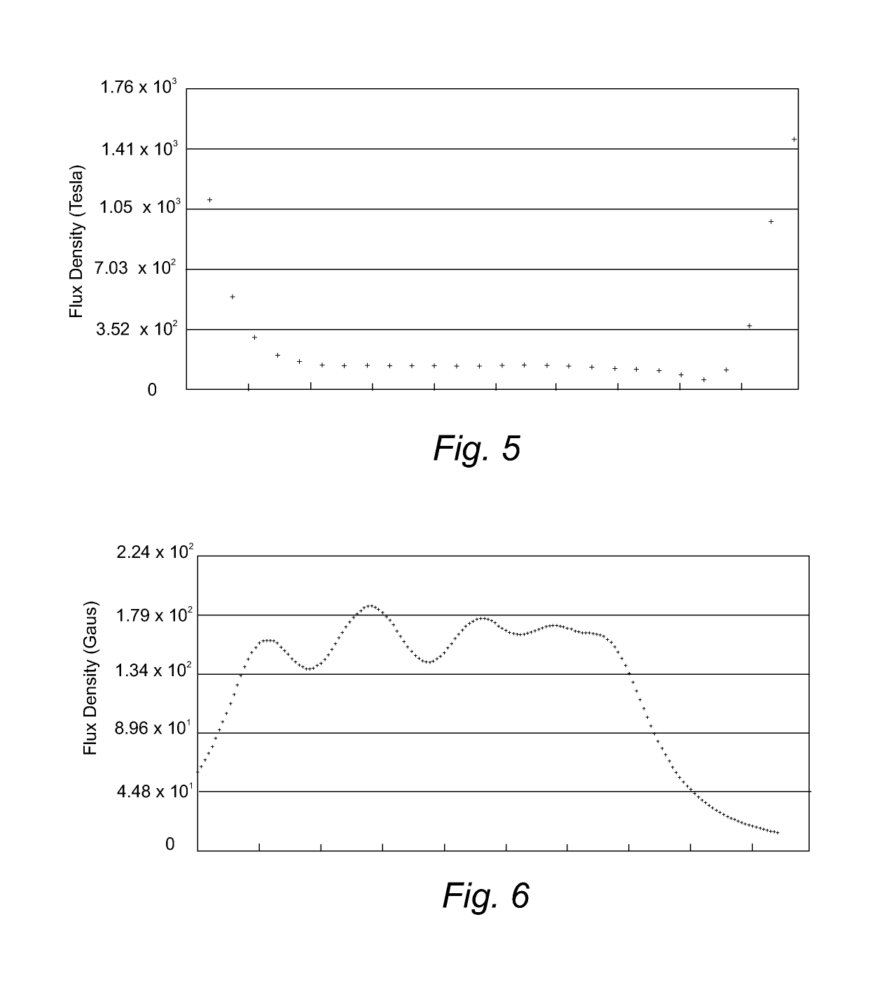

With reference to FIGS. 5 and 6, magnetic flux densities along various directions for the system of FIG. 4A are provided. FIG. 5 provides the flux density along direction by a horizontal axis traversed by substrate along (i.e. d₁ in FIG. 3A) when the solenoids are off. FIG. 6 provides the flux density along direction defined by a horizontal axis traversed by substrate along (i.e. d₁ in FIG. 3A) when the solenoids are on.

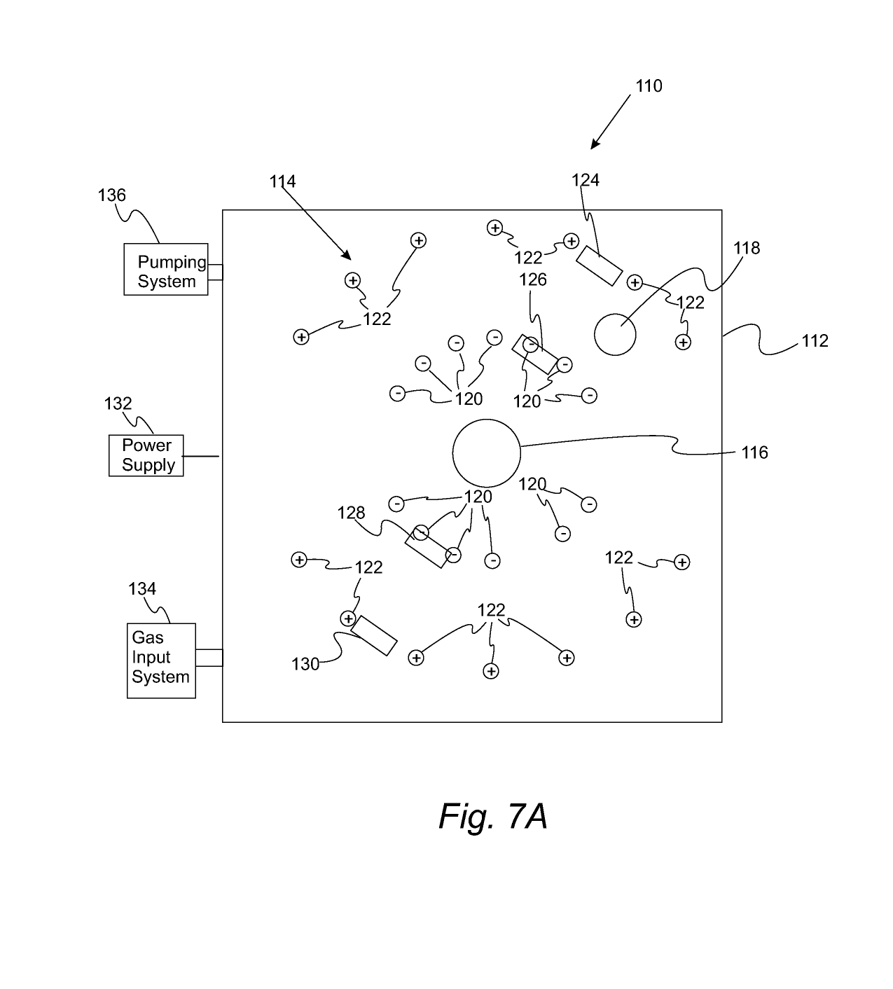

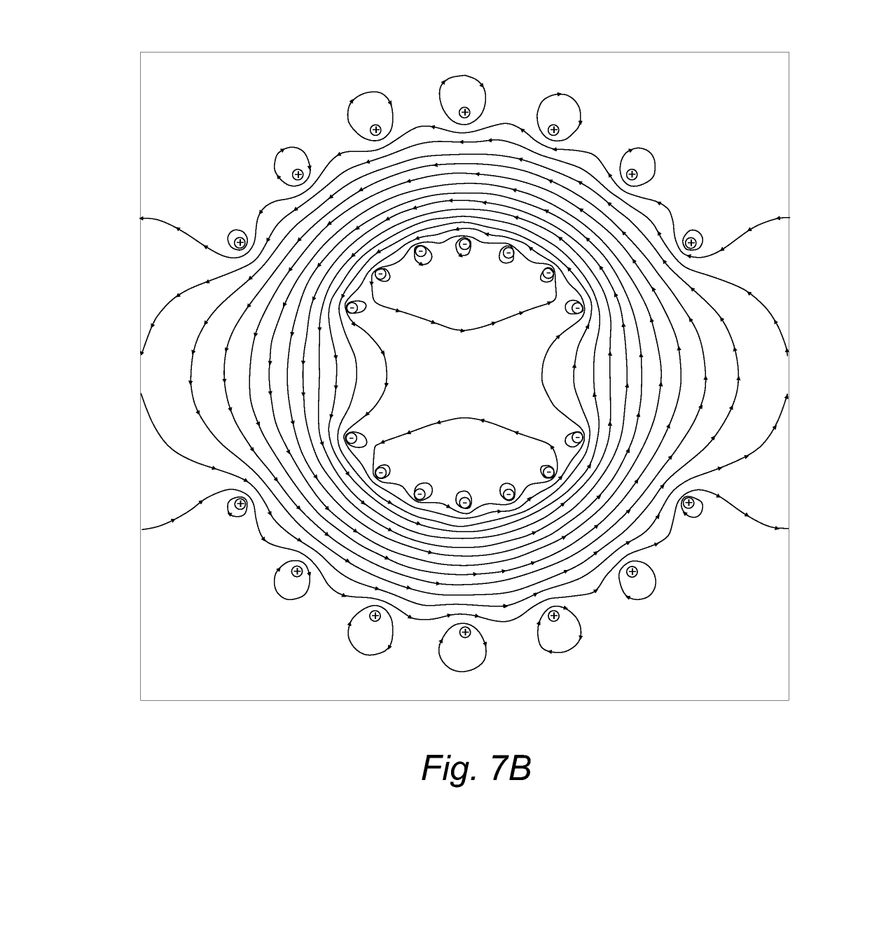

With reference to FIGS. 7A and 7B, the magnetic field for an axially disposed solenoid is provided. FIG. 7A provides a schematic cross section of a system having a curved solenoid. FIG. 7B provides the magnetic field contour line produced from the configuration of FIG. 7A. Sputter coating system 110 includes vacuum chamber 112. Solenoid 114 is disposed about anode 116 which is at the center. Substrate 118 is positioned within the windings of solenoid 114. Solenoid 114 includes inner sections 120 of the coil winding and outer sections 122 of the coil windings Inner sections 120 and outer sections 122 have the opposite polarity. A number of center facing sputter targets 124 and 130 are positioned on the outer section 122 and a number of periphery facing sputter targets 126 and 128 are positioned on the inner section 120. Sputter coating system 110 includes power supply 132, gas input system 134, and pumping system 136. FIG. 7B provides the magnetic field contour lines for the configuration of FIG. 7A which creates a torus contour shape field. In this variation, outer sections 122 are right (have current running in plane) while inner sections 90 are left (have current running out of plane).

The formation of dense defect free coatings using the systems set forth above depends on a number of conditions. Although operation of the present invention does not depend on any particular mechanism, it is hypothesized that the advantages of various embodiment are the result of electron confinement as explained by the following analysis. As an example, consider the formation of a CrN coating generally described by the following reaction:

[Crᵢ]+[Nᵢ]->[CrN] (1)

The index i indicates that there are different energetic forms of species such as Cr (atomic Cr, less energetic), Cr*(excited Cr, intermediate energetic) and Cr (Cr cation, potentially most energetic) and similarly N₂, N₂* and N₂⁺ Now, the actual reaction happens on the substrate surface between the adsorbed species:

[Crᵢ]_{g}->[Crᵢ₋₁]ₛ+qᵢ (2)

and

[Nᵢ]_{g}->[Nᵢ₋₁]ₛ+qᵢ (3)

Reacting to produce:

[Crᵢ₋₁]ₛ[Nᵢ₋₁]ₛ->[CrN]s+q (4)

Equations 2 and 3 state that gaseous chrome and nitrogen species settles on the substrate surface (s) giving off energy/heat (q). The amount of heat given off is a function of the energy of the gaseous species. Energy transfer process takes some small time during which the still energetic atom migrates around on the surface before settling on a low surface energy site. If during this migration on the surface, the somewhat energetic species hit another reactive species a reaction may occur as described by equation 4. Equation 4 states that some substrate energy (qₛ) is required for the reaction to overcome the activation energy for the process to occur. Three extremes can be defined that satisfy equation 4—energetic Cr surface species, energetic N surface species or an energetic surface (e.g., hot, bombarded with energetic species like Ar+ or phonons/laser).

In the case of sputtering, the inherent plasma concentration of energetic target species is somewhat low with the amount of ionized target plasma species being less than 10%. In order for equation 4 to commence forward, the substrate temperature must be raised. Therefore, as compared to deposition sources with highly ionized and energetic target species such as arc (+95%), the substrate temperature is elevated for full reaction in magnetron sputtering. However, there is a down side to high substrate temperatures. For example, it takes heat and time to reach a substrate temperature that allows reaction. In addition, the high substrate temperature allows the formed reacted species to re-crystallize to form large anisotropic crystals. This results in the formation of stable crystalline structures as stated in equation 5.

[CrN]a+qs->[CrN]c+q (5)

This is a process that is hindered at low temperature.

The formal CrN formation requirements can be expressed in a matrix:

$$( \begin{matrix}Plasma \\ Species\end{matrix} ) \times ( \begin{matrix}Species \\ Energy\end{matrix} ) \times ( \begin{matrix}Substrate \\ Parameters\end{matrix} ) = ( \begin{matrix}Deposit \\ Characteristics\end{matrix} ) \qquad ( 6 )$$

The matrix holding the following variables:

$$( \begin{matrix}Sputter & material \\ Active & gas \\ Background & gas\end{matrix} ) \times ( \begin{matrix}Neutral \\ Excited \\ Ionized\end{matrix} ) \times ( \begin{matrix}Substrate & temperature \\ Substrate & roughness \\ substrate & cleanliness\end{matrix} ) = ( \begin{matrix}Implantation & \\ Sputtering & \\ Adhesion & Strength \\ Dense & Amorphous \\ Dense & Crystalline \\ Spongy & \end{matrix} ) \qquad ( 7 )$$

High density of the developing coating is accommodated by energetic species arriving at the surface with a surplus energy that allows them to migrate around on the surface before settling. Arc and sputtering processes only address two of the factors in equation 4, allowing the optimal formation of CrN—high energy of target materials (arc deposition) and in lieu of high energy plasma species, a high substrate temperature (sputtering). Another approach is to create high levels of reactive nitrogen species. This latter approach is not addressed by either sputtering or arc processing. The effect of a magnetic field on an electron is to guide the electron into a forced orbit around field lines with a Larmor radius proportional to the magnetic field strength. The electron linear speed in effect slows down and the electron in return sweeps a large volume thereby increasing the propensity to ionize gas molecules and producing secondary electrons in its path. Embodiments of the present invention take advantage of this behavior to increase the ionic component of plasma, making the plasma more reactive in the vicinity of substrates to be treated. In particular, this is accomplished by aligning the magnetic field along substrate position and path. Certain embodiments of the present invention can be used in concert with one or more of the prior art approaches for substrate activation. Such prior art approaches include, but are not limited to, RF substrate activation using sheath electrons for plasma ionization, substrate pulsing using sheath electrons for plasma ionization, powered anode using sputter electrons for secondary plasma ionization, and laser surface activation.

Variations of the present invention confine sputter electrons (or other sources of electrons such as from arc, glow discharge, arc deposition, electron beam evaporation, and the like) in a magnetic field for secondary plasma ionization thereby creating a high density plasma at the substrate surface. By careful design of the plasma immersion magnetic field, both the concentrations of target, reactive and background gas components of the plasma can be enhanced allowing deposition processes like equation 4 to commence at low temperatures producing dense amorphous coatings. The utilization of a magnetic field for this improvement is a low cost, low maintenance solution that is compatible with standard sputter and arc components. This avoids costly specialized sputter power supplies, radio frequency (RF) and pulse equipment as well as time consuming heating procedures.

Embodiments of the present invention also result in improvement in coating adhesion. Adhesion is substantially determined by covalent bonds formed from the first arriving species on the substrate. Adhesion is improved by using thoroughly cleaned surfaces that are free of free of oils and loosely adhering corrosion products (e.g., oxides). Surfaces may be cleaned by liquid chemistry pre-cleaning procedures, plasma cleaning procedures, and combinations thereof. Inherently, sputtering based processes have problems in achieving good bonding to the substrate surface unless high temperatures are used.

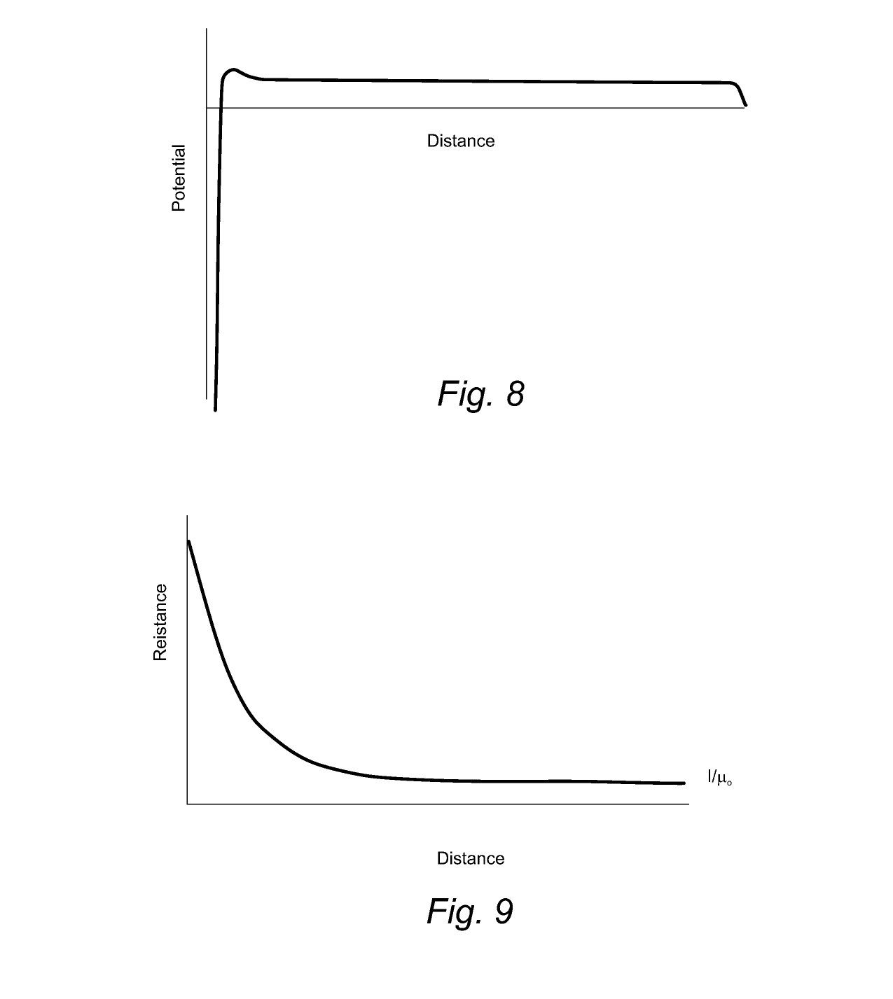

The theoretical background for establishing a plasma involves passing an electron current through a polarized field. FIG. 8 provides the potential from a magnetron cathode to anode in a typical magnetron sputtering system. The negative potential at target surface steeply rises overshooting to +20V before falling back to a plateau and then steeply dropping to zero volts at the grounded anode. The plasma potential is the summation of the effects of electrons and ions. Therefore, FIG. 8 indicates that there is a surplus of cations in most of the cathode anode space. This effect is due to the much faster electrons effectively dragging ions towards the anode. The ions have a longer residence time and slower linear speed than electrons. The electron potential curve has a high gradient at and above target surface due to the magnetic field of the magnetron. Without the magnetic field, the electron potential would increase monotonically towards the anode. The magnetic field forces electrons to move in a spiral path effectively increasing the electron path while slowing down the linear speed. Most importantly, increasing the linear potential drop increases the electron concentration. The increased electron density acts to ionize background gases, vaporize target material and create secondary electrons (cascade magnification). The long volume electron path is utilized to ionize background gas which is accelerated towards the cathode causing sputtering of target material. The vaporized target material is then ionized by primary or secondary electrons with a concentration that peaks at some distance from the cathode where the formation of ionized target material is at maximum. On one side of the maximum, the ion surplus is diluted by acceleration towards sputter surface. On the other side, the ion surplus is lost by diffusion towards the anode and by moving down the plasma potential gradient. The plasma potential is established by a slight overshoot of cations. Towards the anode, the cations are accelerated towards the anode establishing a steep gradient and neutralizing the plasma (i.e., the plasma collapses). The substrate is immersed in the plasma between the cathode and the anode. While the substrate is typically not biased, the plasma nevertheless collapses around the substrate forcing a potential drop and cathodic behavior relative to the plasma. As a result, cations are discharged at the substrate causing deposition, implantation and sputtering depending on substrate bias. In the event of a substrate biased positive, it becomes an anode and effectively pushes the plasma potential up in order to establish the +20V over-potential of the plasma relative to the anode.

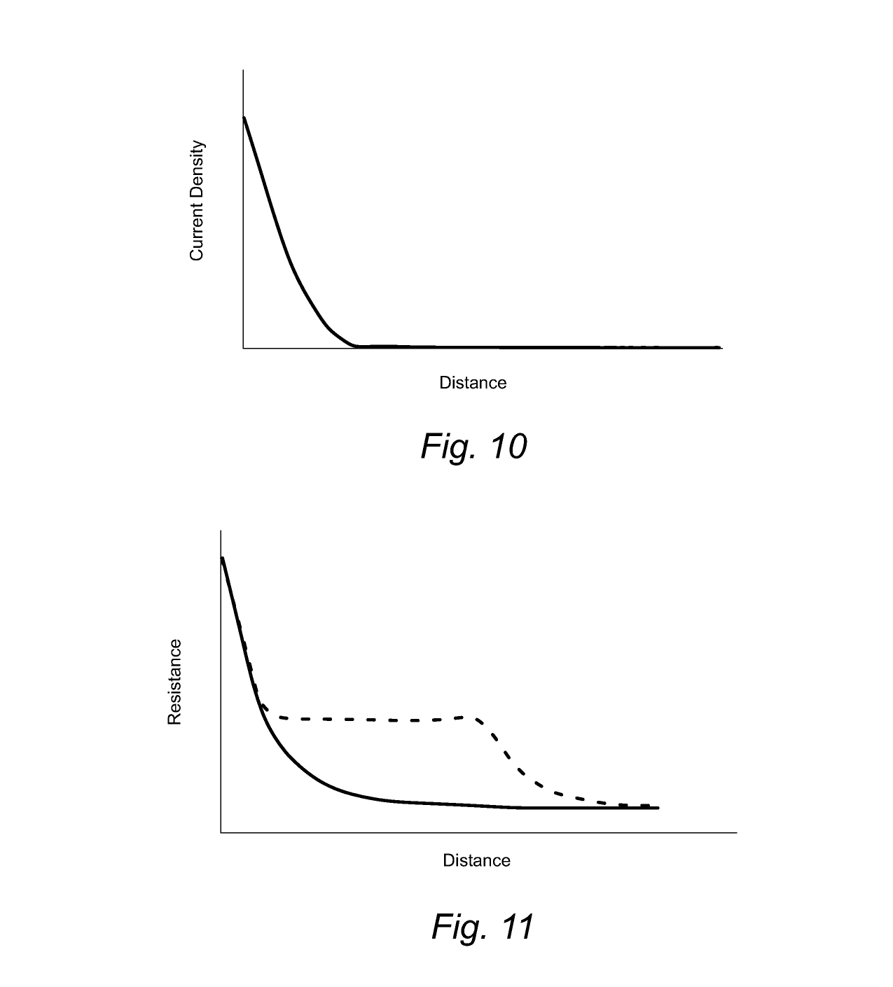

The resistance of the system confined by cathode and anode is determined by vacuum permittivity my₀ close to the anode and increased towards the cathode due to the magnetic field. FIG. 9 provides a principal resistance profile from a magnetron sputter cathode surface towards the anode assuming a declining magnetic field from target surface of the magnetron towards the anode. It is important to realize that the magnetic field represents a resistance that is based on the increased distance the electron traverses while passing the magnetic field. Therefore, the electron traverses a longer distance with the apparent electron concentration being correspondingly high. FIG. 10 provides the principal current density profile from magnetron sputter cathode surface towards anode assuming declining magnetic field contribution from target surface of magnetron.

If an additional magnetic field is introduced by a solenoid, the resistance curve is modified. FIG. 11 provides the principle resistance profile from magnetron sputter cathode surface towards the anode assuming a contribution from the declining magnetic field from the target surface of the magnetron (solid line) in addition to contributions from solenoids (broken line). In the idealized case, the resistance curve reaches a significant plateau some distance from the cathode as illustrated in FIG. 11.

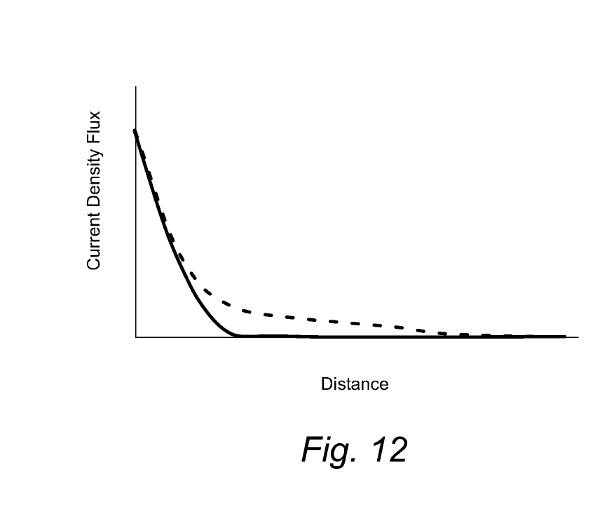

As a result of the increased magnetic field, the electron concentration curve is increased thereby allowing a higher level of ionization in the region occupied by the substrates. This is exactly what is necessary for energetic deposition at low temperature. FIG. 12 provides the principle current density profile from magnetron sputter cathode surface towards an anode assuming a contribution from the declining magnetic field from the target surface of magnetron (solid line) in addition to contributions from solenoids (broken line). The solenoid is observed to mainly affect the electron concentration some distance from the magnetron. Therefore, if a system is properly designed to have additional ionization close to substrates, a dense coating can be realized at lower temperature. It should also be appreciated that it is the fast electrons that create a slip stream vacuum which establishes the plasma potential. Therefore, the anode potential can be increased over ground to increase the plasma potential. The tedious path of the electrons establishes the ionization in front of the sputter that eventually reaches the substrate via diffusion. If a secondary field is established in the substrate zone, the primary and secondary electrons have a second chance of ionizing background species. Advantageously as utilized by embodiments of the present invention, these ions will be close to the substrate surface and facilitate energized deposition (equation 4) to the extent that the background gas consists of neutral target and background gases (e.g., Cr, Ar and N₂) that can be ionized. Embodiment of the present invention increases the resistance of the electron path in order to establish ionization and thereby requiring a higher overall driving potential to pass the same current. The driving potential can either be established towards ground or relative to a powered floating anode. In either case, the potential is raised without changing the magnetron potential gradient at magnetron surface. The advantage of using a powered anode separated by solenoid field from the cathode is to drive the current drain through the resistive magnetic field path while forcing secondary ionization around the substrates.

The following examples illustrate the various embodiments of the present invention. Those skilled in the art will recognize many variations that are within the spirit of the present invention and scope of the claims.

### Example 1

A coating is deposited utilizing the equipment depicted in FIG. 7A configured with four magnetron sputters facing outward and Cr targets. The sputter targets are powered at 15 kW and a magnetic field is generated by passing 200 A through a 27 turn solenoid. The forced central anode is polarized to +50 volts relative to ground and the substrate is rotated around sputter targets and biased at −50 volts relative to ground collecting a bias current of 18 A. During the 30 minutes deposition, a background pressure of 5 mT is maintained by supplying a mixture of argon and nitrogen. A fully reacted 3 micron thick CrN coating with shiny appearance and amorphous characteristics is obtained as evident from SEM cross-section.

### Reference Example

In a parallel experiment, the experimental conditions of Example 1 are copied except that the solenoid is not turned on. The collected bias current is 4 A. The resulting CrN coating is sub-stoichiometric with regard to nitrogen. The coating also shows optical haze along with columnar features as evident from SEM cross-section.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A vacuum deposition system for forming dense coatings, the vacuum deposition comprising:
a substrate holder for holding a substrate, the substrate having a substrate surface to be coated;
a magnetic field generator that generates a magnetic field in which the substrate is at least partially immersed such that a component of the magnetic field is parallel to the substrate surface, the magnetic field having a strength at the substrate surface between 5 and 1000 Gauss;
an optional electron source;
an electron drain; and
a deposition source that provides material to coat the substrate, wherein the vacuum deposition system includes the optional electron source if the deposition source does not provide a source of electrons.

2. The vacuum deposition system of claim 1 wherein the magnetic field generator comprises a solenoid.

3. The vacuum deposition system of claim 1 wherein the magnetic field is solenoidal.

4. The vacuum deposition system of claim 1 wherein a solenoidal magnetic field generator has a linear configuration such that the substrate moves linearly through the solenoidal magnetic field.

5. The vacuum deposition system of claim 1 wherein the solenoidal magnetic field generator has an axial configuration such that the substrate moves axially through the solenoidal magnetic field.

6. The vacuum deposition system of claim 5 wherein the magnetic field has a rectangular cross section.

7. The vacuum deposition system of claim 1 wherein the magnetic field is periodically reversed at a frequency between 0.1 and 110 Hz.

8. The vacuum deposition system of claim 1 wherein the component of the magnetic field parallel to the substrate surface has a magnitude that is at least 50% of the total magnitude of the magnetic field.

9. The vacuum deposition system of claim 1 further comprising an electron source and an electron drain.

10. The vacuum deposition system of claim 1 wherein the deposition source includes an electron source.

11. The vacuum deposition system of claim 1 wherein the deposition source includes an electron drain.

12. The vacuum deposition system of claim 1 wherein the deposition source includes a magnetron sputtering source.

13. The vacuum deposition system of claim 1 wherein the substrate is electrically floating.

14. The vacuum deposition system of claim 1 wherein the substrate is electrically negatively biased.

15. The vacuum deposition system of claim 1 wherein the deposition source is operated in sputtering mode.

16. The vacuum deposition system of claim 1 wherein the deposition source is 1 operated in arc mode.

17. The vacuum deposition system of claim 1 wherein the deposition source is operated in electron beam evaporation mode.

18. A vacuum deposition system for forming dense coatings, the vacuum deposition comprising:
an electron source;
an electron drain;
a substrate having a substrate surface to be coated;
a solenoidal magnetic field generator that generates a magnetic field in which the substrate is at least partially immersed such that a component of the magnetic field is parallel to the substrate surface, the magnetic field having a strength at the substrate surface between 5 and 1000 Gauss; and
a deposition source that provides material to coat the substrate.

19. The vacuum deposition system of claim 18 wherein the solenoidal magnetic field generator has a linear configuration such that the substrate moves linearly through the solenoidal magnetic field.

20. The vacuum deposition system of claim 18 wherein the solenoidal magnetic field generator has an axial configuration such that the substrate moves axially through the solenoidal magnetic field.

21. A method of coating a substrate with a dense coating, the method comprising:
providing a substrate having a substrate surface;
generating a magnetic field in which the substrate is at least partially immersed such that a component of the magnetic field is parallel to the substrate surface, the magnetic field having a strength at the substrate surface between 5 and 1000 Gauss;
passing an electron current through the magnetic field; and
depositing material on the substrate from a deposition source.
